(19) United States
(12) Patent Application Publication
(10) Pub. No.: US 2007/0264790 A1
(43) Pub. Date: Nov. 15, 2007

(54) METHOD OF MANUFACTURING SEMICONDUCTOR DEVICE

(75) Inventors: Whee Won Cho, Cheongju-si (KR); Jung Geun Kim, Seoul (KR); Suk Joong Kim, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: HYNIX SEMICONDUCTOR INC., Kyoungki-do (KR)

(21) Appl. No.: 11/557,885

(22) Filed: Nov. 8, 2006

(30) Foreign Application Priority Data
May 12, 2006 (KR) 2006-42992

(51) Int. Cl. H01L 21/762

(52) U.S. Cl. 438/424; 438/435

(57) ABSTRACT

A method of manufacturing semiconductor devices includes forming a trench in a predetermined region of a substrate. A first insulating layer and a second insulating layer are formed on a entire surface so that the trench is gap-filled. The first and second insulating layers are polished until a top surface of the substrate is exposed. A wet etch process of a low selectivity is performed, so that a portion of the first insulating layer remains on sides of the trench while stripping the second insulating layer. A third insulating layer is formed on the entire surface, so that the trench is gap-filled, thereby forming an isolation structure.

### BACKGROUND

The present invention relates to a method of manufacturing semiconductor devices and more particularly, to a method of manufacturing semiconductor devices, in which isolation trenches can be fully gap-filled without voids.

Localized oxidation isolation (LOCOS) and shallow trench isolation (STI) are the two common methods for creating an isolation structure. As the level of integration of semiconductor devices increases, the process of forming an isolation structure becomes more difficult, especially for the LOCOS method. Accordingly, the isolation structure for highly integrated devices is formed by a Shallow Trench Isolation (STI) method by forming a trench in a semiconductor substrate and gap filling the trench.

The STI method can be implemented several ways. Using a NAND flash memory device as an example, one of the methods is sequentially etching a tunnel oxide layer, a polysilicon layer, and a hard mask layer to form a trench and then forming an oxide layer on the entire surface in such a way as to gap fill the trench. However, highly-integrated devices have a trench with a deep depth compared with the entry width of the trench, which makes it difficult to gap fill the trench without generating a void.

In gap-filling the trench with the oxide film, the opening of the trench has a deposition speed faster than that of the bottom of the trench. Accordingly, an over-hang phenomenon is generated in which the entry of the trench is clogged as the oxide layer is deposited. It results in the creation of a void in the trench.

The trench gap-fill method used to solve the problem generally includes one of the following methods. A first method involves forming an oxide layer in the trench by employing High Density Plasma (HDP), etching the oxide layer thickly formed at the entry portion of the trench in order to widen the opening of the trench, and then forming an oxide layer in the trench in order to prevent voids from occurring. A second method involves changing the gap-fill material, i.e., gap-filling a trench using a Spin On Dielectric (SOD) material.

The first trench gap-fill method can be applied to 90 nm devices. However, it becomes less advantageous when applied to 70 nm devices because deposition, wet etching, and deposition must be repeatedly performed increasing the production time and cost. Also it is even more difficult to apply for 60 nm devices. Furthermore, there is a reliability problem caused by the use of fluorine (F). That is, during gap filling process using fluorine (F), fluorine (F) can incorporate with tunnel oxide and results in EOT (Electrical Oxide Thickness) increase and physical tunnel oxide thickness increase. So the program Vt and program speed of flash memory decreases.

The second trench gap-fill method is also problematic in the reliability of the device and in cost of materials due to an increased unit cost depending on the type of SOD material used. That is, due to impurity contained in SOD material, the quality of tunnel oxide can be degraded. Normally “Cycling Vt shift” becomes large depending on the volume of SOD material used.

### SUMMARY OF THE INVENTION

Accordingly, the present invention addresses the above problems and describes a method of manufacturing semiconductor devices in which trenches can be gap-filled without voids by employing a polishing process and a low selectivity wet etch process.

According to an aspect of the present invention, there is provided a method of manufacturing a semiconductor device, including the steps of; forming a trench in a predetermined region of a semiconductor substrate; sequentially forming a first insulating layer and a second insulating layer on a entire surface so that the trench is gap-filled; polishing the first and second insulating layers until a top surface of the semiconductor substrate is exposed; performing a low selectivity wet etch process so that a portion of the first insulating layer remains on the sidewalls of the trench while stripping the second insulating layer; and forming a third insulating layer on the entire surface so that the trench is gap-filled, thereby forming an isolation structure.

### BRIEF DESCRIPTION OF THE DRAWINGS

FIGS. 1A to 1C are cross-sectional views sequentially shown to illustrate a method of manufacturing a semiconductor device according to an embodiment of the present invention.

### DETAILED DESCRIPTION OF EMBODIMENTS

The various embodiments according to the present patent will be described with reference to the accompanying drawings.

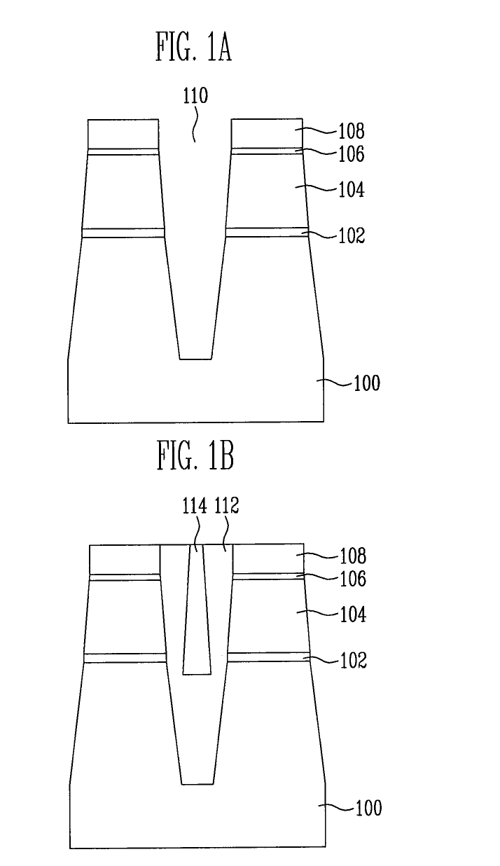

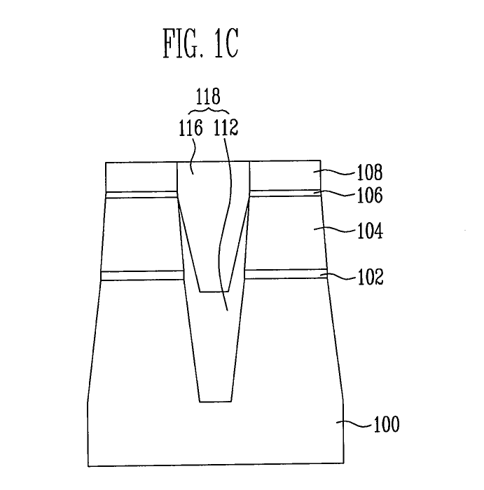

Referring to FIG. 1A, a tunnel oxide layer 102, a polysilicon layer 104 for a floating gate, a buffer layer 106, and a hard mask layer 108 are sequentially formed on a semiconductor substrate 100. The buffer layer 106 may be composed of an oxide layer and the hard mask layer 108 may be composed of a nitride layer. The hard mask layer 108 is patterned by a photolithography process. The buffer layer 106, the polysilicon layer 104, the tunnel oxide layer 102, and the semiconductor substrate 100 are sequentially etched to a predetermined depth using the patterned hard mask layer 108 as a mask, thus forming a trench 110.

Referring to FIG. 1B, a first insulating layer 112 is formed on the entire surface including the trench 110. At this time, the first insulating layer 112 may be formed using a HDP oxide layer. An over-hang phenomenon occurs at the opening of the trench 110 when the trench 110 is partially gap-filled.

A second insulating layer 114 is formed on the entire surface so that it fully gap-fills the trench 110. The second insulating layer 114 may be formed using Spin On Glass (SOG), Boron Phosphorus Silicate Glass (BPSG) or O₃-TEOS (Tetra Ethyl Ortho Silicate). The first and second insulating layers 112 and 114 are polished until the top surface of the hard mask layer 108 is exposed.

Referring to FIG. 1C, the second insulating layer 114 is stripped by a low selectivity wet etch process and dry etch process. The etch selectivity of the second insulating layer 114 to the first insulating layer 112 may be set between 2:1 to 8:1. As the second insulating layer 114 is stripped, a portion of the first insulating layer 112 remains on the sides of the polysilicon layer 104 while the over-hang phenomenon at the opening of the trench 110 is removed.

A third insulating layer 116 is formed on the entire surface so that the trench 110 is fully gap-filled. The third insulating layer 116 is polished until a top surface of the hard mask layer 108 is exposed, thereby forming an isolation structure 118. The third insulating layer 116 may be composed of a HDP oxide layer. Accordingly, the trench 110 is completely gap-filled without void.

As described above, in accordance with the method of manufacturing the semiconductor devices according to the present invention, manufacturing cost can be reduced by applying inexpensive SOG to the process.

Furthermore, a trench can be gap-filled without voids by applying a low selectivity wet etch process.

Although the foregoing description has been made with reference to the various embodiments, it is to be understood that changes and modifications of the present patent may be made by those skilled in the art without departing from the spirit and scope of the present patent and appended claims.

What is claimed is:

1. A method of manufacturing a semiconductor device, comprising the steps of:
forming a trench in a predetermined region of a semiconductor substrate;
providing a first insulating layer within the trench to at least partly fill the trench and over the semiconductor substrate, the first insulating layer having an over-hang at an opening of the trench;
providing a second insulating layer within the trench and over the first insulating layer;
removing the second insulating layer and the over-hang of the first insulating layer; and
providing a third insulating layer within the trench over the first insulating layer to form an isolation structure.
The method of claim 1, wherein a hard mask is provided over the substrate and defining the opening of the trench, the method further comprising:

2. The method of claim 1, polishing the first and second insulating layers until the hard mask is exposed prior to removing the second insulating layer and the over-hang.

3. The method of claim 1, wherein the removing step involves a wet etch process.

4. The method of claim 3, wherein the wet etch process involves a low selectivity process, so that a portion of the first insulating layer remains on sides of the trench while stripping the second insulating layer.

5. The method of claim 4, wherein an etch selectivity of the second insulating layer to the first insulating layer is no more than 8:1.

6. The method of claim 5, wherein the etch selectivity is at least 2:1.

7. The method of claim 1, wherein the second insulating layer is substantially removed from the trench.

8. The method of claim 7, wherein the second insulating layer is stripped from the trench.

9. The method of claim 1, wherein the first and third insulating layers are formed of a HDP oxide layer.

10. The method of claim 1, wherein the second insulating layer is formed of SOG, BPSG or O₃-TEOS.

11. The method of claim 1, wherein the first and third insulating layers are of the same kind, and the second insulating layer is of a different kind.

12. The method of claim 1, wherein the removing step involves a dry etch process.

13. The method of claim 12, wherein the wet etch process involves a low selectivity process, so that a portion of the first insulating layer remains on sides of the trench while stripping the second insulating layer.

14. The method of claim 13, wherein an etch selectivity of the second insulating layer to the first insulating layer is no more than 8:1.

15. The method of claim 14, wherein the etch selectivity is at least 2:1.
